(19) United States
(12) Patent Application Publication
(10) Pub. No.: US 2007/0190811 A1
(43) Pub. Date: Aug. 16, 2007

(54) Method of forming patterns and/or pattern data for controlling pattern density of semiconductor devices and pattern density controlled semiconductor devices

(76) Inventors: Sung-gyu Park, Suwon-si (KR); Myoung-jun Jang, Yongin-si (KR); Ji-young Shin, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/655,222

(22) Filed: Jan. 19, 2007

(30) Foreign Application Priority Data
Feb. 13, 2006 (KR) 10-2006-0013768

(51) Int. Cl. H01L 21/00

(52) U.S. Cl. 438/800

(57) ABSTRACT

A method of forming a pattern for a semiconductor device includes forming first pattern data, forming second pattern data, forming third pattern data, forming pattern density measurement data including the first, second, and third pattern data, measuring a pattern density of the pattern density measurement data, adjusting shapes of patterns in the third pattern data based on a comparison of the measured density value and a reference density so as to form fourth pattern data, and forming final pattern data including the first, second, and fourth pattern data.

### BACKGROUND OF THE INVENTION

1. Field of the Invention

The present invention relates to methods of adjusting and/or controlling a pattern density of a semiconductor device, and such a density pattern adjusted semiconductor device. More particularly, the invention relates to a method of adjusting a density of a pattern or pattern data according to a design rule of a semiconductor device.

2. Description of the Related Art

With the development of semiconductor manufacturing techniques, the line width(s) of elements of semiconductor devices is decreasing to about several tens of nanometers. The line width(s) of elements of semiconductor devices is projected to be several nanometers in the near future. With rapidly developing manufacturing techniques for highly integrated semiconductor devices, it is difficult to form internal patterns without considering a minimum line width of an element(s) the semiconductor device and the internal patterns of the elements constituting the semiconductor device. That is, even when a same semiconductor device manufacturing process is implemented, different process results that depend on a pattern density of a semiconductor device may be obtained. The difference may be particularly large when a CMP process. a photolithography or etching process is performed on an area or device with various pattern densities. Such a phenomenon results from a load effect caused by the pattern density.

Therefore, in order to reduce or eliminate such instability or variation(s) in the processing and operation of semiconductor devices as a result of differences in pattern densities of semiconductor devices, it is desired to make the densities of the patterns uniform. Thus, to achieve stability in the manufacturing process and the operation of semiconductor devices, dummy patterns may be inserted between pattern layers of semiconductor devices.

However, dummy patterns should have different densities according to the different pattern densities of semiconductor devices. Accordingly, in order to reduce or eliminate unnecessary processing, to improve the reliability and yield of semiconductor devices, and to reduce manufacturing cost of the semiconductor devices, etc., the optimization of dummy pattern densities based on different pattern densities of semiconductor devices and the incorporation of the dummy patterns should be performed according to standard rules and processes.

### SUMMARY OF THE INVENTION

The present invention is therefore directed to semiconductor devices and methods of manufacturing semiconductor devices, which substantially overcome one or more of the problems due to the limitations and disadvantages of the related art.

It is therefore a feature of an embodiment of the invention to provide a semiconductor device pattern(s) and a method of forming a semiconductor device pattern(s), in which methods, rules and standards for inserting dummy patterns are determined and implemented.

At least one of the above and other features and advantages of the present invention may be realized by providing a method of forming pattern data for a semiconductor device, the method including forming first pattern data, forming second pattern data, forming third pattern data, forming pattern density measurement data including the first, second, and third pattern data, measuring a pattern density of the pattern density measurement data, adjusting shapes of patterns in the third pattern data based on a comparison of the measured density value and a reference density so as to form fourth pattern data, and forming final pattern data including the first, second, and fourth pattern data.

The first pattern data may be active pattern data, the second pattern data may be gate pattern data, and the third and fourth pattern data may be dummy pattern data. The fourth pattern data may have patterns that are obtained by adjusting at least one of a width, a length and an interval of patterns in the third pattern data. The fourth pattern data may have patterns that are obtained by adjusting the widths or lengths of the patterns in the third pattern data to proportional to a pattern density of the pattern density measurement data and/or the intervals of the patterns in the third pattern data to be inversely proportional to the pattern density of the pattern density measurement data.

The first pattern data and the third pattern data or fourth pattern data may be incorporated into one pattern data. The method of forming pattern data for a semiconductor device, the method may include forming reference pattern data, forming first pattern data having different pattern densities, forming second pattern data, measuring a pattern density by overlapping the reference pattern data and the second pattern data, and selecting first pattern data corresponding to the measured pattern density among the first pattern data having different pattern densities.

The first pattern data may be an active pattern data of the semiconductor device, and the second pattern data may be gate pattern data of the semiconductor device. The reference pattern data may be active pattern data of the semiconductor device. The first pattern data having different pattern densities may include main pattern data and dummy pattern data. The main pattern data may have a fixed shape and size, and the dummy pattern data may have different shapes and sizes.

At least one of the above and other features and advantages of the present invention may be separately realized by providing a method of forming a pattern for a semiconductor device, the method including forming a first pattern, forming a second pattern, measuring a total pattern density when the first pattern and the second pattern overlap each other, comparing the measured density and a reference pattern density to form a third pattern, and forming a final pattern in which the second pattern and the third pattern overlap each other.

The first pattern and the third pattern may be active patterns, and the second pattern may be a gate pattern. The third pattern may have patterns that are obtained by adjusting at least one of a width, a length, and an interval of a pattern in the first pattern. The widths and lengths of some patterns in the third pattern may be adjusted to be in inverse proportion to the total pattern density, and the intervals of some patterns in the third pattern may be adjusted to be in proportion to the total pattern density.

At least one of the above and other features and advantages of the present invention may be separately realized by providing a semiconductor device including a first semiconductor element that has a first main pattern density and a first dummy pattern density, and a second semiconductor element that has a second main pattern density and a second dummy pattern density, wherein a ratio of the first main pattern density and the second main pattern density may be inversely proportional to a ratio of the first dummy pattern density and the second dummy pattern density.

A difference between the first and second dummy pattern densities is a difference in width, length, or interval of dummy patterns. The width and length of each of the dummy patterns is inversely proportion to a difference between the first and second main pattern densities, and the interval between the dummy patterns is proportional to the difference between the first and second main pattern densities.

The dummy patterns may be a plurality of linear or segmental patterns that are formed parallel to each another. The dummy patterns may be a plurality of at least one of square patterns and polygonal patterns. The dummy patterns may be separated from the conductive patterns in the semiconductor device.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A to 1D illustrate flow charts of methods of forming patterns or pattern data of a semiconductor device according to various exemplary embodiments of the invention;

FIGS. 2A to 2C illustrate exemplary first, second and third patterns;

FIG. 2D illustrates an exemplary reference pattern including the first and third patterns illustrated in FIGS. 2A to 2C;

FIGS. 2D to 2G illustrate adjusted versions of the exemplary third pattern illustrated in FIG. 2C;

FIGS. 2H to 2J illustrate the exemplary third patterns illustrated in FIGS. 2D to 2G along with the exemplary first and second patterns illustrated in FIGS. 2A and 2B;

FIGS. 3A and 3B illustrate additional exemplary embodiments of a third pattern together with the first and second patterns illustrated in FIGS. 2A and 2B; and

FIGS. 4A to 4D illustrate exemplary final patterns or final pattern data corresponding to combinations of the first and second patterns and the exemplary third patterns illustrated in FIGS. 2C, 2E, 2F and 2G, respectively.

### DETAILED DESCRIPTION OF THE INVENTION

Korean Patent Application No.10-2006-0013768 filed on Feb. 13, 2006 in the Korean Intellectual Property Office, and entitled: “Method of Forming Pattern Data of Semiconductor Device Adjusting Pattern Density and Semiconductor Device Using the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or element, or intervening layers or elements may also be present. Further, it will be understood that when a layer or element is referred to as being “under” another layer, it can be directly under, and one or more intervening layers or elements may also be present. In addition, it will also be understood that when a layer or element is referred to as being “between” two layers or elements, it can be the only layer between the two layers or elements, or one or more intervening layers or elements may also be present. Like reference numerals refer to like elements throughout.

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the thicknesses of layers and regions are exaggerated for clarity. Like reference numerals refer to like elements throughout the specification.

Embodiments of the invention are described herein with reference to cross-sectional illustrations that are schematic illustrations of idealized embodiments of the invention. As such, variations from the shapes of the illustrations as a result of, e.g., manufacturing techniques and/or tolerances, are to be expected. Thus, embodiments of the invention should not be construed as limited to the particular shapes of regions illustrated herein but are to include deviations in shapes that result from, e.g., manufacturing. Therefore, the regions illustrated in the figures are schematic in nature and their shapes are not intended to illustrate the actual shape of a region of a device and are not intended to limit the scope of the invention.

In the description, pattern formation may describe a pattern(s) actually formed on a wafer during manufacture of a semiconductor device, or a pattern(s) formed for layout design, simulation, photomask manufacturing, etc. That is, the patterns may be actual patterns, visual patterns that are implemented on a computer monitor, or a program that is implemented by a chain of commands, etc.

In general, a circuit is designed to serve a particular function(s) and then, patterns corresponding to, e.g., physical layers, of the circuit are implemented on a wafer. Before the corresponding patterns are generated, the designed circuit is simulated and optimized, and a general arrangement plan, e.g., chip plan, for arranging the elements on the wafer may be set forth. The structural drawing may be, e.g., a two-dimensional plan view of the semiconductor device, in which all the patterns may be shown. The structural drawing may then be classified by layers, and a corresponding pattern may be designed for each photomask. In some embodiments, the designed patterns on the photomask may be visual patterns. In such cases, the visual pattern may enable a workeder to visually confirm or identify each pattern. However, program data for actually producing the photomask may not be visual, and may be, e.g., a program including an array of commands. For example, in an apparatus for producing photomasks, the patterns may be input as a machine language program including, e.g., a plurality of sequentially arranged commands.

In the following description of exemplary embodiments, the term “patterns” may be employed to describe, among other things, all of the above-described concepts. That is, e.g., patterns may be patterns serving as visual structures for confirmation, identification, etc. with patterns having shapes corresponding to portions, e.g., layers of the semiconductor device(s). More particularly, as discussed above, program data may be, e.g., computer data employed during design or pattern layout, or may be machine language program data for the apparatus for producing the photomasks or visual data that allows a worker to visibly confirm or identify, etc., the patterns during photomask production.

Therefore, in the following description, data may be, e.g., circuit data on a computer for manufacturing the semiconductor device, computer layout data employable during a layout process of implementing the designed circuit on a silicon substrate, data for producing the photomasks, etc. The data for producing the photomasks may be, e.g., data implemented on the computer or mechanical data employable by the apparatus for producing the photomasks. In the following description, the term “photomask” includes reticles, and data for an electron beam direct rendering system, as well as photomasks.

In the following description, the term “pattern density” is used. The term “density” herein is used together with the pattern density. More specifically, density may refer to unit elements in a semiconductor chip, like one transistor, or a density of patterns that are implemented on single-layer pattern data or photomask data for manufacturing a semiconductor device. The respective pattern density may be obtained by calculating a pattern area to a total area of pattern data to be measured, and may be expressed by Equation 1.

D=Ap/At {Equation 1}

In Equation 1, D may correspond to a pattern density, Ap may correspond to a pattern area, and At may correspond to a total area.

Generally, in the photomask, a region through which light passes may be referred to as a clear region, and a region through which light does not pass may be referred to as a dark region. Patterns that may be exposed to light passing through the photomask may be referred to as clear patterns, and patterns that are not exposed to light may be referred to as dark patterns.

Therefore, the pattern density can be expressed by Equations 2 and 3, provided below.

Dd={(Ad)/(Ad+Ac)}=(Ad/At) {Equation 2}

Dc={(Ac)/(Ac+Ad)}=(Ac/At) {Equation 3}

In Equations 2 and 3, Dd may correspond to a dark pattern density, Dc may correspond to a clear pattern density, Ad may correspond to a total area of dark patterns, Ac may correspond to a total area of clear patterns, and At may correspond to a total area of both the clear and dark patterns.

Therefore, a high pattern density may indicate that a total area of a respective one of the dark patterns or clear patterns is high. More particularly, a high pattern density may indicate the respective corresponding patterns are densely formed. In contrast, a low pattern density may indicate that a total area of a respective one of the dark patterns or clear patterns is low. In the following description, unless specified otherwise, reference to “patterns” correspond to dark patterns to help focus the description on the technical spirit of one or more aspects of the invention, but may in fact correspond to dark or clear patterns depending on characteristics of the processing method(s) employed. Therefore, low pattern density may indicate that the patterns, e.g., dark patterns, are not densely formed.

Depending on an actual method employed during fabrication of a semiconductor device, the dark and clear patterns may or may not result in actual patterns. For example, during a semiconductor device manufacturing process, the dark and clear patterns may depend upon whether positive photoresist or negative photoresist is employed. In cases employing positive photoresist, photoresist regions that are exposed to light may be developed and patterned as the clear patterns. In cases employing negative photoresist, photoresist regions that are exposed to light may not be eveloped and patterned as the dark patterns.

In embodiments of the invention, the dark and clear patterns may be replaced with each other using a simple command from a computer or apparatus for design or photomask production. In the accompanying figures, the dark patterns are illustrated, but the invention is not limited to dark patterns.

In the following description, the phrase “total pattern density” may correspond to a total pattern density of one semiconductor device. The total pattern density may be obtained by totaling densities of all the regions of the semiconductor device. For example, the total pattern density may be obtained by totaling an average density for each region of the semiconductor device.

A high or low density may be defined in relation to a density of similar elements and not necessarily in relation to fifty percent thereof or other absolute references. For example, a current pattern density can be defined to be high or low based on a density of semiconductor devices manufactured without employing one or more of the technical aspects of the invention or other elements of devices manufactured according to methods employing one or more aspects of the invention. Further, in a subsequent semiconductor device manufacturing process, the density of elements or patterns to be measured may be defined to be high or low based on current measured density data of the patterns. Therefore, in the following description, reference to a density being high or low is fluid, and does not have an absolute reference point. More particularly, in the following description, although the term “reference density” is used, the term does not refer to an absolute value, as described above. The reference density may be, e.g., a density of a previously manufactured semiconductor device or a density that is arbitrarily set by a manufacturer.

The respective pattern density may be expressed by comparing a plurality of semiconductor devices. When the plurality of semiconductor devices are not the same element, even if the pattern densities are similar to one another, they may not be truly consistent with one another. In such cases, it may be expressed that the plurality of semiconductor devices or an individual semiconductor device(s) have/has a relatively high or low pattern density.

In the following description, the term “formation” of pattern data of the semiconductor device is used. However, the pattern data of a semiconductor device may not be visible. The term “generation” may also be used rather than the term “formation”. Further, forming pattern data may also include changing or revising previously formed pattern data. Therefore, the terms “formation” or “forming” used herein includes, e.g., “generating,” “changing,” “revising,” etc.

The term “dummy pattern” used herein means patterns that are not employed for passing an electrical signal(s) in an electrical signal of the semiconductor device. More specifically, the electrical signal of the semiconductor device may or may not flow in the dummy pattern. If the electrical signal(s) of the semiconductor device flow in the dummy pattern(s), that flow of such electrical signal should generally not have an effect on the basic operation of the semiconductor device. Further, the terms “active pattern” and “gate pattern” used herein mean conductive patterns that are formed in different layers of the semiconductor device. In the description, the terms “active pattern” and “gate pattern” are used to simplify descriptions of exemplary embodiments of the invention, but embodiments of the invention are not limited thereto. Other patterns, in which the electrical signal flow, may be used.

Hereinafter, exemplary methods of forming pattern data of a semiconductor device according to one or more aspects of the invention will be described in detail with reference to the accompanying drawings.

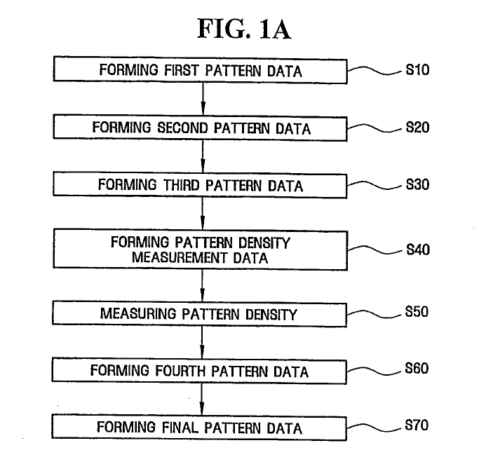

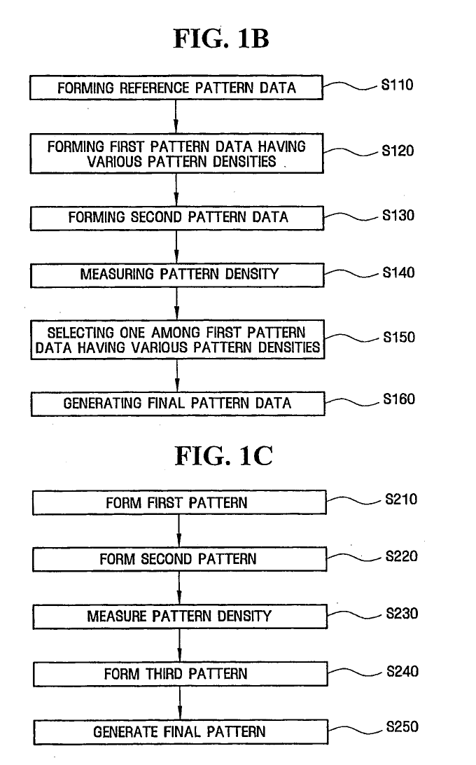

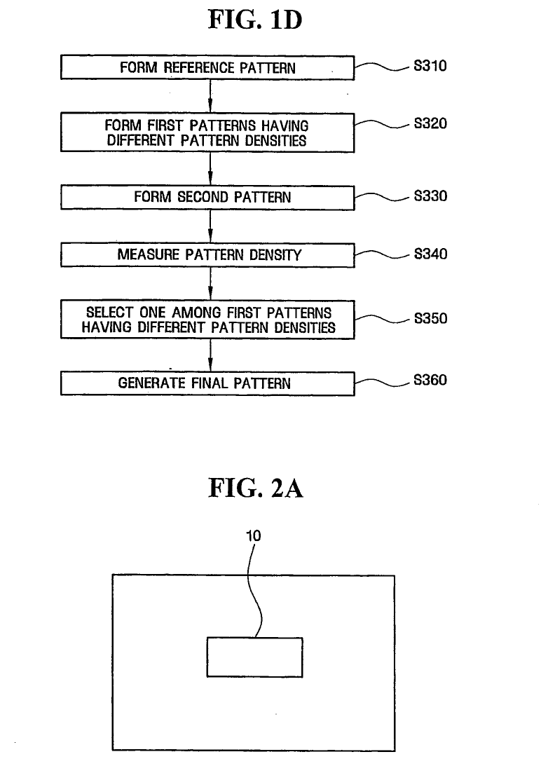

FIGS. 1A to 1D illustrate flowcharts of first through fourth exemplary methods for forming patterns or pattern data of a semiconductor device according to one or more aspects of the invention.

Referring to FIG. 1A, a first exemplary method of forming pattern data for a semiconductor device according to an embodiment of the invention may include forming first pattern data S10, forming second pattern data S20, forming third pattern data S30, forming pattern density measurement data S40, measuring a pattern density of the pattern density measurement data including the first, second and third pattern data S50, adjusting the third pattern data according to the measured pattern density to form fourth pattern data S60, and forming final pattern S70. As discussed below, in some embodiments of the invention, forming final pattern data S70 may include the first, second and fourth pattern data.

The second pattern data may be pattern data that extends over or below the first pattern data. Some, all or no portion of the second pattern data may overlap or cross the first pattern data. For example, the first pattern data may be active pattern data, and the second pattern data may be gate pattern data. More particularly, e.g., the first pattern data and the second pattern data may respectively correspond to first and second layers of a semiconductor device, where the first and second layers may each extend along an XY plane, and the first and second layers may be stacked and/or at least partially overlapping along a Z direction that is substantially perpendicular to an XY plane.

The third pattern data may be pattern data that extends adjacent to portions of the first and second pattern data and/or pattern data that does not overlap the first and second data patterns along the Z direction. That is, e.g., although the third pattern may overlap the first and/or second patterns along the X and/or Y directions, the third pattern data may not overlap the first and/or second patterns along the Z direction, e.g., direction along which the first and second pattern data may overlap each other. For example, the third pattern data may be pattern data formed in a blank region where the first and second pattern data do not exist along the XY plane(s). For example, the third pattern data may extend along an XY plane between respective portions of the first and second pattern data. In embodiments of the invention, third pattern data may be dummy pattern data.

The third pattern data and/or the fourth pattern data and the first pattern data or the second pattern data may be incorporated into one pattern data. For example, the third pattern data or the fourth pattern data and the second pattern data may be incorporated into one pattern data.

More particularly, the third pattern data and/or fourth pattern data may be included with the first pattern data or the second pattern data. That is, the third pattern data and/or the fourth pattern data may be data included with the first pattern data or the second pattern data, and/or other pattern data. More specifically, e.g., the dummy pattern of the third pattern data and/or the fourth pattern data may be included with the active pattern of the first pattern data. Alternatively, e.g., the dummy pattern of the third pattern data and/or the fourth pattern data may be included with the gate pattern of the second pattern data.

The fourth pattern data may be formed by correcting or adjusting the third pattern data. Specifically, the fourth pattern data may be formed by adjusting, e.g., a width(s), a length(s) and/or an interval(s) of a pattern(s) in the third pattern data. Since the third pattern data may be dummy pattern data, the fourth pattern data may be formed by adjusting, e.g., a width(s), a length(s) and/or an interval(s) of the dummy pattern(s). Unit patterns in the third and fourth pattern data, e.g., the dummy patterns, may be a plurality of one-dimensional patterns such as linear and/or segmental patterns and/or may be two-dimensional patterns such as square and/or polygonal patterns. The plurality of patterns may be formed parallel to each other.

Alternatively, the fourth pattern data may be added to and/or may replace, i.e., substitute for, the third pattern data. For example, the fourth pattern data may be a selected one or portion(s) among a plurality of third pattern data that was previously prepared and divided. In such cases, e.g., a portion of the divided data may correspond to the third data and another portion of the divided data may correspond to the fourth data.

In some embodiments, a portion of the fourth data may be directed to correcting, adjusting or substituting for the third data and another portion of the fourth data may be directed to additional dummy pattern(s). In some embodiments, no portion of the fourth data may be directed to correcting or adjusting the third pattern data and the fourth data may completely substitute for the third data. However, in a broad sense, even such substituting or additional data may be considered to be “correcting data” or “adjusting data”.

Although reference may only be made to first, second, third and fourth pattern data, embodiments of the invention are not limited to such first to fourth pattern data.

In the first exemplary embodiment illustrated in FIG. 1A, a pattern density may be measured after forming the first, second, third pattern data S10-S30. After forming pattern density measurement data S40, however, embodiments of the invention are not limited to such a processing regimen. For example, the pattern density may be measured at different point(s) in the process.

In some cases, the measure pattern density may be within a desired range, and thus, no adjustment to the third data may be necessary. In some embodiments of the invention, after a pattern density is measured, if the measured pattern density data is high, the fourth pattern data may be formed by decreasing a density of the third pattern data, and if the measured pattern density data is low, the fourth pattern data may be formed by increasing the density of the third pattern data. More particularly, when the pattern density is to be decreased, the fourth pattern data may be formed by decreasing a line width(s), decreasing a line length(s) and/or increasing a line interval(s), etc. When the pattern density is to be increased, the fourth pattern data may be formed by increasing a line width(s), increasing a line length(s) and/or decreasing a line interval(s), etc.

More particularly, e.g., in embodiments of the invention, based on the measured pattern density data, the pattern(s) of the third pattern data may be adjusted or controlled based on the fourth pattern data, and the line widths and/or lengths of patterns in the fourth pattern data may be inversely proportional to the measured pattern density data, and the line interval(s) between patterns in the fourth pattern data may be proportional to the measured pattern density data.

In some embodiments of the invention, the pattern density measurement data may be formed by combining only the first and second pattern data. The pattern density of the formed pattern density measurement data including only the first and second pattern data may then be measured. In such embodiments of the invention, e.g., the third pattern data may include a plurality of different-density areas, and one of plurality of different-density areas may be selected.

In some embodiments of the invention, the final pattern data may include the first pattern data, the second pattern data, and the fourth pattern data, e.g., cases in which the fourth pattern data substituted for the third pattern data. In some embodiments of the invention, the final pattern data may include the first pattern data, the second pattern data, and the third pattern data, e.g., cases in which the third pattern data required no adjustment(s). In some embodiments of the invention, the final pattern data may include the first pattern data, the second pattern data, the third pattern data and the fourth pattern data.

FIG. 1B illustrates a flowchart showing a second exemplary method of forming pattern data of a semiconductor device employing one or more aspects of the invention.

Referring to FIG. 1B, the method of forming pattern data of a semiconductor device according to the second exemplary embodiment of the invention may include forming reference pattern data S110, forming first pattern data including different pattern densities S120, forming second pattern data S130, overlapping the reference pattern data and the second pattern data to measure a pattern density S140, selecting first pattern data having a pattern density corresponding to the measured pattern density among the first pattern data having different pattern densities S150, and forming final pattern data including the selected first pattern data and the second pattern data S160.

In embodiments of the invention, the reference pattern data and the first pattern data may include active pattern data of the semiconductor device and the second pattern data may include a gate pattern data. The reference pattern data and the first pattern data may include dummy patterns.

The first pattern data may include different pattern densities by,. e.g., including dummy patterns with different shapes in a pattern area, by including a plurality of patterns having different pattern densities. In embodiments of the invention, the plurality of patterns having different pattern densities may have a density relationship such that various combinations thereof may provide a plurality of total pattern densities such that a plurality of the patterns having different pattern densities may be included to provide a desired total pattern density.

For example, the first pattern data having different pattern densities may be one pattern data including main patterns having a same pattern density and dummy patterns having different pattern densities, a plurality of pattern data including different main patterns having different pattern densities and dummy patterns having a same pattern density, a plurality of pattern data including different main patterns having a same pattern density and dummy patterns having different pattern densities, a plurality of pattern data including different main patterns having different pattern densities and dummy patterns having different pattern densities, etc.

More particularly, e.g., in some embodiments in which the first pattern data includes different pattern densities, the line width(s), length(s) and/or interval(s) of the dummy patterns may be different from each other. That is, e.g., the first pattern data may include main pattern data having a same shape and size as that of the reference pattern data, and dummy pattern data having different shapes and/or sizes.

As described with reference to FIG. 1A, in embodiments including a linear dummy pattern, a width of the lines may be narrowed or widened to provide different densities. In embodiments including a segmental dummy pattern, widths, lengths, and/or horizontal and/or vertical interval(s) of the segments may be adjusted to provide different densities. In embodiments including a two-dimensional dummy pattern having, e.g., a square or polygonal shape, the area(s) and/or interval(s) may be adjusted to provide different densities.

FIG. 1C illustrates a flowchart of a third exemplary method of forming patterns of a semiconductor device according to one or more aspects of the invention.

Referring to FIG. 1C, a method of forming patterns of a semiconductor device according to an embodiment of the invention may include forming a first pattern S210, forming a second pattern S220, overlapping the first pattern and the second pattern to measure a total pattern density S230, comparing the total pattern density with a reference density to form a third pattern S240, and forming a final pattern including the second pattern and the third pattern S250.

The first pattern and the third pattern may be active patterns including dummy patterns, and the second pattern may be a gate pattern.

The first pattern and the third pattern may include active patterns having a same shape and size and dummy patterns having different shapes and sizes. More specifically, e.g., the third pattern may have a different width, length, area, or interval than that of the first pattern.

Measurement of the total pattern density can be performed by overlapping the first pattern and the second pattern. In some cases, the first pattern may include dummy patterns and in other cases, the first pattern day may not include dummy patterns. More particularly, for example, for selecting among different patterns and/or densities, a state of the conductive paths for transmitting electrical signals of the semiconductor device may be a key factor in the selection and in some cases dummy patterns may serve to improve signal transmission while in other cases dummy patterns may hinder signal transmission. Accordingly, the pattern density may be measured in a state where the dummy patterns are included or in a state where the dummy patterns are excluded.

Further, after the third pattern is formed, the second pattern and the third pattern may be overlapped, and the total pattern density may be measured again. In this case, another pattern, e.g., a fourth pattern, may be formed. Thus, in some embodiments, some of the steps of the exemplary method illustrated in the flowchart shown in FIG. 1C may be repeated.

The third pattern may be formed by adjusting widths, lengths, and/or intervals of some patterns in the first pattern. The widths or lengths of some patterns may be adjusted in a manner that is inversely proportional to the pattern density of the measured density measurement data according to the measured total pattern density and/or the intervals of some patterns in the first pattern may be adjusted in a manner that is proportional to the measured total pattern density. Here, some patterns may be dummy patterns.

FIG. 1D illustrates a flowchart of a fourth exemplary method of forming patterns of a semiconductor device according to one or more aspects of the invention.

Referring to FIG. 1D, a method of forming patterns of a semiconductor device according to the fourth exemplary embodiment of the invention may include forming a reference pattern S310, forming first patterns having different pattern densities S320, forming a second pattern S330, overlapping the reference pattern and the second pattern so as to measure a total pattern density S340, selecting one of the first patterns having different pattern densities corresponding to the measure total pattern density S350, and forming a final pattern S360.

The reference pattern and the first pattern may be active patterns of a semiconductor device including dummy patterns, and the second pattern may be a gate pattern.

The first pattern data may include different pattern densities by, e.g., including dummy patterns with different shapes in a pattern area and/or by including a plurality of patterns having different pattern densities.

The first pattern data may include different pattern densities by, e.g., including dummy patterns with different shapes in a pattern area, by including a plurality of patterns having different pattern densities. In embodiments of the invention, the plurality of patterns having different pattern densities may have a density relationship such that various combinations thereof may provide a plurality of total pattern densities such that a plurality of the patterns having different pattern densities may be included to provide a desired total pattern density.

For example, the first pattern data having different pattern densities may be one pattern data including main patterns having a same pattern density and dummy patterns having different pattern densities, a plurality of pattern data including different main patterns having different pattern densities and dummy patterns having a same pattern density, a plurality of pattern data including different main patterns having a same pattern density and dummy patterns having different pattern densities, a plurality of pattern data including different main patterns having different pattern densities and dummy patterns having different pattern densities, etc.

More particularly, e.g., in some embodiments in which the first pattern data includes different pattern densities, the line width(s), length(s) and/or interval(s) of the dummy patterns may be different from each other. That is, e.g., the first pattern data may include main pattern data having a same shape and size as that of the reference pattern data, and dummy pattern data having different shapes and/or sizes.

The technical spirit of the invention will now be further described with reference to the accompanying drawings. The patterns shown in the drawings may have shapes different from those of illustrated in the accompanying drawings, and embodiments of the invention are not limited to the illustrated shapes. Further, the illustrations illustrated in the accompanying drawings may be exaggerated or simplified.

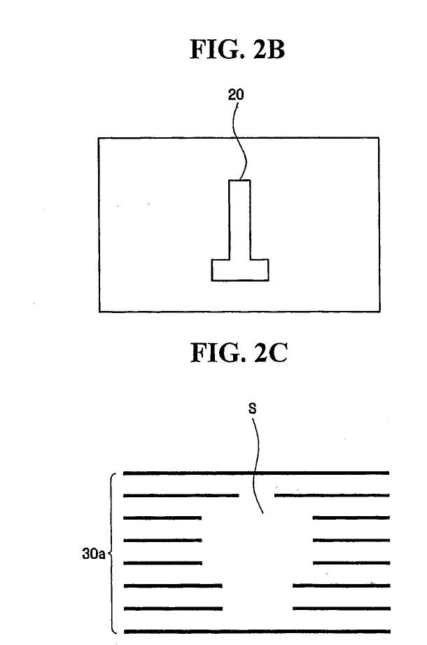

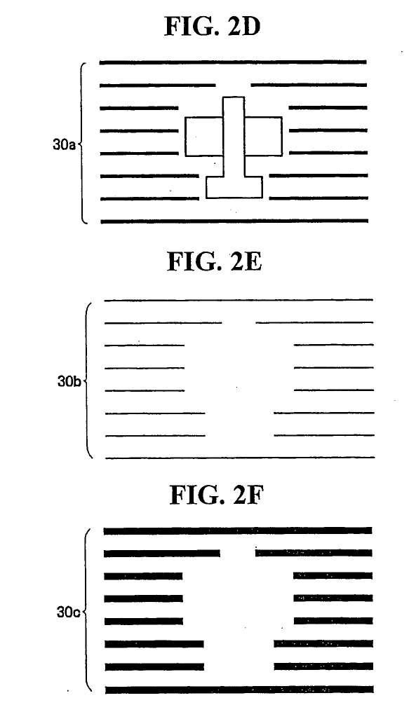

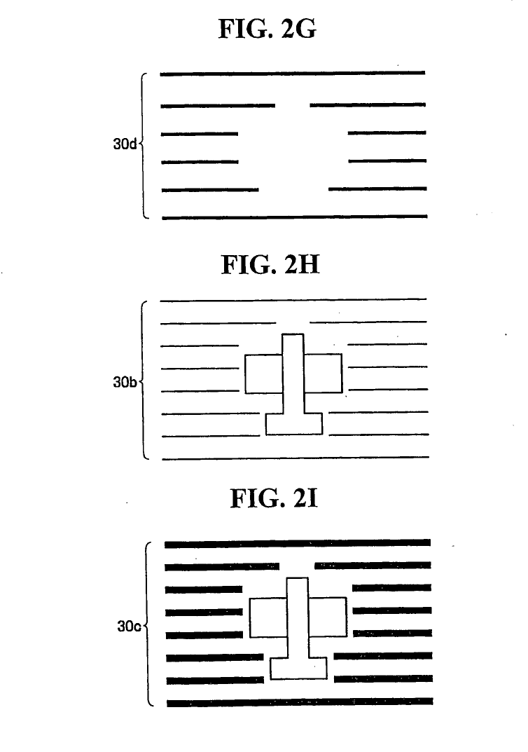

FIGS. 2A to 2C illustrate exemplary first, second and third patterns, FIG. 2D illustrates an exemplary reference pattern including the first and third patterns illustrated in FIGS. 2A to 2C, FIGS. 2D to 2G illustrate adjusted versions of the exemplary third pattern illustrated in FIG. 2C, and FIGS. 2H to 2J illustrate the exemplary third patterns illustrated in FIGS. 2D to 2G along with the exemplary first and second patterns illustrated in FIGS. 2A and 2B.

In the descriptions of FIGS. 2A to 2J, it is assumed that one unit element pattern is formed on a computer monitor. However, this assumption is just to simplify the description of one or more aspects of the invention and to aid in understanding of the invention. Actually, many unit element patterns may be shown on the computer monitor. In addition, the patterns may be actually implemented on the photomask or semiconductor wafer. These are common in view of visual shapes, and, if the individual cases are described with the individual drawings, the repetitive description will be given with reference to the similar drawings. Therefore, although the description of only one case is given, it is possible for those skilled in the art to sufficiently understand other cases through an expanded concept. Hereinafter, the description will be given by way of one example for common understanding.

The descriptions of the drawings will emphasize an active pattern and a gate pattern that are basic patterns of a unit element serving as a basic unit of a circuit. Other patterns can be applied, but the drawings may be complex, which may make it difficult to understand the technical aspects of the invention. Therefore, only the active pattern and the gate pattern are used in the following description and the accompanying drawings. In addition, for better understanding of the technical aspects of the invention, one pattern is shown. Actually, in cases where many patterns are formed, various embodiments of the invention can be performed.

Referring to FIG. 2A, a first pattern 10 may be formed. The first pattern 10 may be an active pattern. As described above, the first pattern 10 may be a pattern that is formed on the computer monitor, the photomask, or the wafer.

In FIG. 2A, the exemplary first pattern 10 having a bar shape is illustrated. However, patterns having various shapes may be implemented.

FIG. 2B illustrates a second exemplary pattern 20 that may be formed. The second pattern 20 may be a gate pattern. As described above, the second pattern 20 may be a pattern that is formed on the computer monitor, the photomask, or the wafer.

The second pattern 20 is shown to have a segmental shape, but is not limited thereto. The second pattern 20 may have, e.g., a long linear shape.

Further, when one unit element is formed, a contact or via that transmits/receives an electrical signal to/from an overlying signal transmission line may be formed at one end of the unit element. For this reason, in FIG. 2B, one end of the second pattern 20 is formed wider. If the contact or via is not formed, the second pattern 20 may be a segmental shape.

The second pattern 20 of FIG. 2B may be arranged to overlap the first pattern 10 of FIG. 2A.

FIG. 2C illustrates an exemplary third pattern 30a that may be formed. The third pattern 30a may be a dummy pattern 30a.

The third pattern 30a may be implemented in a linear shape, a segmental shape, a dot shape, other polygonal shapes, etc. FIG. 2C illustrates the third pattern 30a having a linear shape. However, it should be noted that this is not intended to limit the scope of the technical aspect of the invention.

Referring to FIG. 2C again, the third pattern 30a may include a region S where the linear patterns are discontinuous. The region S may be a region where the first pattern 10 and the second pattern 20 of FIGS. 2A and 2B overlap each other and/or a region corresponding to where the first pattern 10 and the second pattern 20 overlap an XY plane. As discussed above, in embodiments of the invention, the third pattern 30a may be designed to overlap the first pattern 10 and the second pattern 20 along the X and/or Y directions, but may not overlap the first pattern 10 and the second pattern 20 along the Z direction.

FIG. 2D illustrates a combination of the first pattern 10, the second pattern 20, and the third pattern 30a stacked on each other. As described above, the first pattern 10 and the second pattern 20 may at least partially overlap each other, and the third pattern 30a may not overlap the first pattern 10 and the second pattern 20 along the Z direction. In some embodiments, the pattern illustrated in FIG. 2D may be the reference pattern.

Intervals may be provided among the first pattern 10, the second pattern 20, and the third pattern 30a. The intervals may be according to a design rule of the elements. Since the drawings are conceptual and exaggerated, i.e., not real, the patterns shown in the drawing may be different from the patterns of the actual elements. In the actual elements, the intervals may be half or more of the design rule. The design rule may correspond to a sum of the line width of a gate and the line interval between the gates or a line width of the gate.

After, e.g., the first, second and third patterns are stacked, the total pattern density may be measured. The measurement of the total pattern density may be performed using a pattern density measurement apparatus. Further, the total pattern density may be calculated from the computer pattern data.

The third pattern can be adjusted according to the measured total pattern density. Adjusted versions of the third pattern are illustrated in FIGS. 2E to 2G.

Referring to FIG. 2E, illustrating a first adjusted version of the third pattern 30b, when the measured total pattern density is high, a line width of a third pattern 30b may be adjusted to be narrower than a line width of the reference pattern shown in FIG. 2D. For example, when the measured total pattern density is higher than a reference density of the reference pattern, e.g., pattern shown in FIG. 2D, in order to reduce the total pattern density, the line width of the third pattern 30b may be narrowed, and thus the pattern density of the third pattern 30b can be adjusted to be lower. Therefore, the total pattern density may be adjusted corresponding to the reference density.

Referring to FIG. 2F, illustrating a second adjusted version of the third pattern 30c, when the measured total pattern density is low, a line width of a third pattern 30c may be adjusted wider than the line width of the reference pattern shown in FIG. 2D. For example, when the measured total pattern density is lower than the reference density, e.g., density of reference pattern shown in FIG. 2D, in order to increase the total pattern density, the line width of the third pattern 30c may be widened, and thus the pattern density of the third pattern 30c can be adjusted to be higher. Therefore, the total pattern density may be adjusted corresponding to the reference density.

In FIG. 2G, illustrating a third adjusted version of the third pattern 30d, when the measured total pattern density is high, a line interval between third patterns 30d may be adjusted to be wider than a reference line interval of the reference pattern shown in FIG. 2D. When the measured total pattern density is higher than the reference density, in order to reduce the total pattern density, the line interval between the third patterns 30d may be adjusted, and thus the pattern density of the third pattern 30d may be adjusted to be lower. Therefore, the total pattern density may be adjusted corresponding to the reference density.

FIGS. 2H to 2J illustrate the exemplary third patterns 30b, 30c, 30d illustrated in FIGS. 2D to 2G along with the exemplary first and second patterns 10, 20 illustrated in FIGS. 2A and 2B.

FIG. 2H shows a pattern including the first pattern 10, the second pattern 20, and the third pattern 30b shown in FIG. 2E. As compared with FIG. 2D, since the line width of the third pattern 30b is made narrower, the pattern density of the third pattern 30b is reduced. Therefore, it can be seen that the total pattern density is also reduced.

FIG. 2I shows a pattern including the first pattern 10, the second pattern 20, and the third pattern 30c shown in FIG. 2F. As compared with FIG. 2D, since the line width of the third pattern 30c is made wider, the pattern density of the third pattern 30c is increased. Therefore, it can be seen that the total pattern density is also increased.

FIG. 2J shows a pattern including the first pattern 10, the second pattern 20, and the third pattern 30d shown in FIG. 2G. As compared with FIG. 2D, since the line interval between the third patterns 30d is made wider, the pattern density of the third pattern 30d is reduced. Therefore, it can be seen that the total pattern density is also reduced.

Though not shown, the pattern density of the third pattern 30a can be increased by making the line interval between the third patterns 30 narrower, and thus the total pattern density can be increased.

Further, the third pattern 30a can be adjusted by making the line length of the third pattern 30a longer or shorter, and thus the total pattern density can be adjusted.

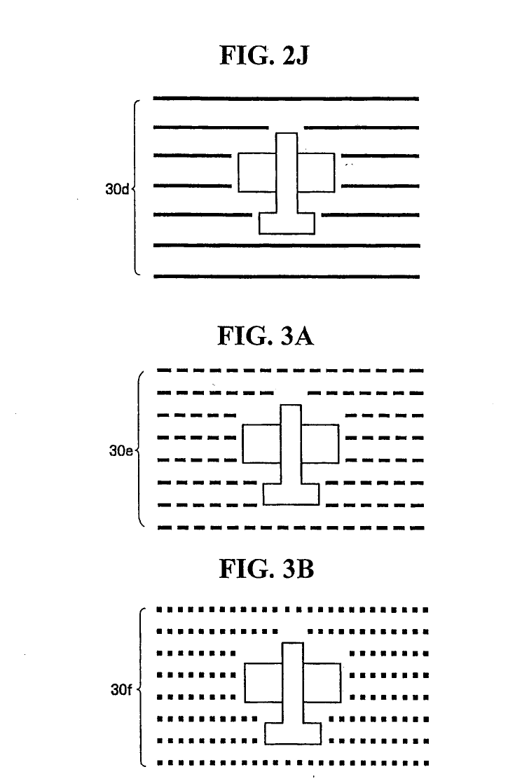

FIGS. 3A and 3B illustrate additional exemplary embodiments of a third pattern together with the first and second patterns illustrated in FIGS. 2A and 2B.

Referring to FIG. 3A, instead of the linear third pattern 30a shown in FIG. 2D, segmental patterns 30e may be formed.

Therefore, as compared with the linear pattern, a method of adjusting the lengths of the segments can be further applied.

Referring to FIG. 3B, instead of the one-dimensional pattern shown in FIG. 2D, two-dimensional patterns 30f may be formed.

For example, referring to FIG. 3B, square patterns 30f may be formed. In this case, since the patterns are two-dimensional, the pattern density can be adjusted by a method of adjusting an area of each unit pattern and an interval between the unit patterns. In some embodiments of the invention, polygonal patterns having various shapes may be formed.

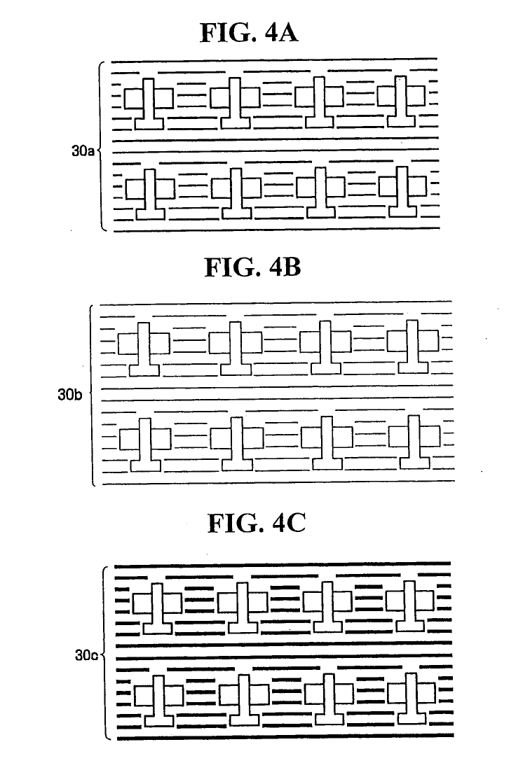

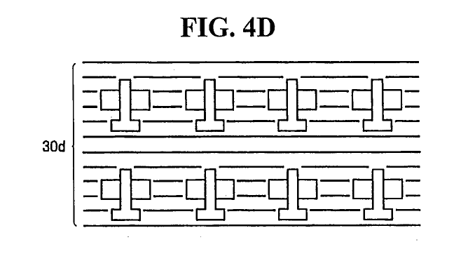

FIGS. 4A to 4D illustrate diagrams of final patterns and final pattern data formed by an exemplary method of forming patterns or pattern data of a semiconductor device according to one or more aspects of the invention. More particularly, FIGS. 4A to 4D illustrate exemplary final patterns or final pattern data corresponding to combinations of the first and second patterns 10, 20 and the exemplary third patterns 30a, 30b, 30c, 30d illustrated in FIGS. 2C, 2E, 2F and 2G, respectively.

FIG. 4A shows the shapes of the internal patterns of a semiconductor device that includes a final pattern having the patterns 30a or pattern data shown in FIG. 2C.

FIG. 4B shows the shapes of the internal patterns of a semiconductor device that includes a final pattern having the patterns 30b or pattern data shown in FIG. 2E.

FIG. 4C shows the shapes of the internal patterns of a semiconductor device that includes a final pattern having the patterns 30c or pattern data shown in FIG. 2F.

FIG. 4D shows the shapes of the internal patterns of a semiconductor device that includes a final pattern having the patterns 30d or pattern data shown in FIG. 2G.

Table 1 illustrates a case when a semiconductor device is manufactured according to one or more aspects of the invention. In particular, linear dummy patterns were used as dummy patterns, and a method that adjusts the line width so as to adjust the total pattern density was applied.

TABLE 1

| | Line Width | Increase/ |
|---|---|---|
| Pattern | of Dummy | Decrease |
| Density (D, %) | Pattern (μm) | Result (%) |
| D < 35.5 | 1.00 | 8↑ |
| 35.5 ≦ D < 36.5 | 0.95 | 7↑ |
| 36.5 ≦ D < 37.5 | 0.90 | 6↑ |
| 37.5 ≦ D < 38.5 | 0.85 | 5↑ |
| 38.5 ≦ D < 39.5 | 0.80 | 4↑ |
| 39.5 ≦ D < 40.5 | 0.75 | 3↑ |
| 40.5 ≦ D < 41.5 | 0.70 | 2↑ |
| 41.5 ≦ D < 42.5 | 0.65 | 1↑ |
| 42.5 ≦ D < 43.5 | 0.60 | 0 |
| 43.5 ≦ D < 44.5 | 0.55 | 1↓ |
| 44.5 ≦ D < 45.5 | 0.50 | 2↓ |
| 45.5 ≦ D < 46.5 | 0.45 | 3↓ |
| 46.5 ≦ D < 47.5 | 0.40 | 4↓ |
| 47.5 ≦ D < 48.5 | 0.35 | 5↓ |
| 48.5 ≦ D | 0.30 | 6↓ |

Table 1 shows a change in the measured total pattern density when the density was changed by ±1% on the basis of the density of the typical semiconductor device, that is, 42.5%≦D<43.5%, and the line width of the dummy pattern was changed by 0.05 μm.

The pattern density D is a measured pattern density in a case where the total pattern density was adjusted while the line width of the dummy pattern is changed according to the density, and then the total pattern density was measured again.

It can be seen that it may be possible to linearly increase and decrease the total pattern density by adjusting the line width of the dummy pattern.

Table 2 shows an application example for various semiconductor devices.

TABLE 2

| Line Width | | | | | | |
|---|---|---|---|---|---|---|
| of Dummy | | | | | | |
| Pattern | Element Type and Pattern Density (%) | | | | | |
| (μm) | A | B | C | D | E | F |
| 0.3 | 34.9 | 37.1 | 36.3 | 35.0 | 41.3 | 40.0 |
| 0.4 | 36.5 | 38.1 | 38.5 | 37.4 | 43.3 | 42.0 |
| 0.5 | 38.0 | 39.1 | 40.7 | 40.4 | 45.3 | 44.0 |
| 0.6 | 39.6 | 40.1 | 42.9 | 42.4 | 47.2 | 46.0 |
| 0.7 | 41.1 | 41.1 | 45.2 | 44.9 | 49.2 | 48.1 |
| 0.8 | 42.7 | 42.1 | 47.3 | 47.4 | 51.1 | 50.1 |
| 0.9 | 44.3 | 43.1 | 49.6 | 49.9 | 53.1 | 52.0 |
| 1.0 | 45.9 | 44.2 | 51.8 | 52.5 | 55.1 | 54.0 |

A, B, C, D, E, and F are semiconductor devices according to different design rules or design. Therefore, when the same dummy pattern is applied, different total pattern densities are obtained.

Referring to Table 2, various semiconductor devices show an approximately linear change in the total pattern density according to the adjustment of the density of the dummy patterns, like the measurement result of a specified semiconductor device in Table 1. Therefore, if the reference pattern density is known, adjustments needed based on the measured total pattern density and the general effect of such adjustments for forming the final pattern density may be determined or calculated. For example, in the element A, when a target pattern density is 41.9%, the optimum total pattern density can be obtained by applying the dummy patterns of about 0.75 μm. Further, in the element F, when a target pattern density is 43%, the optimum total pattern density can be obtained by applying the dummy patterns of about 0.45 μm.

Semiconductor devices according to an embodiment of the invention include a first semiconductor device having a first main pattern density and a first dummy pattern density, and a second semiconductor device having a second main pattern density and a second dummy pattern density. A ratio between the first main pattern density and the second main pattern density may be inversely proportional to a ratio between the first dummy pattern density and the second dummy pattern density.

The first main pattern density may be a density of active patterns of the first semiconductor device, and the first dummy pattern density may be a density of dummy patterns that are formed in the same layer as the active patterns.

The second main pattern density may be a density of active patterns of the second semiconductor device, and the second dummy pattern density may be a density of dummy patterns that are formed in the same layer as the active patterns.

A difference between the first and second dummy pattern densities may be a difference between the widths, lengths, or intervals of the dummy patterns.

The width and length of each of the dummy patterns may be inversely proportional to a difference between the first and second pattern densities, and the interval between the dummy patterns may be proportional to the difference between the first and second pattern densities.

The dummy patterns may be a plurality of linear or segmental patterns that are formed in parallel with one another.

The dummy patterns may not be in contact with conductive patterns of the semiconductor device, i.e., patterns that can transmit/receive the electrical signals so as to contribute to the operation(s) of the semiconductor device. The dummy patterns can be manufactured so as not to be in electrical contact with these elements.

Though not shown, the patterns having various shapes described herein can be expanded and applied.

The semiconductor devices, in particular, logic elements that can actively process given commands have various product groups, various internal structures, and pattern densities. That is, even in the same product group, the elements can be manufactured to have various internal structures and pattern densities. More specifically, even the semiconductor devices that process the same command by the same process can be manufactured to have various structures according to different applications. In such cases, the basic circuitry is the same, but layout design of transistors and signal lines may vary. In addition, various semiconductor devices can be manufactured to share a plurality of unit circuit blocks. That is, different kinds of semiconductor devices can be manufactured to have the same circuitry and the same unit element structure.

In all cases, the pattern density of each of the semiconductor devices is important to manufacture the semiconductor devices by a stable process. The appropriate arrangement of the dummy patterns in each of the semiconductor devices according to the pattern density may be accompanied by an increase in stable operation and reliability of the semiconductor device and an increase in yield.

Therefore, the technical spirit of the invention is suitable for stably manufacturing the semiconductor device according to characteristics of various products.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming pattern data for a semiconductor device, the method comprising:
forming first pattern data;
forming second pattern data;
forming third pattern data;
forming pattern density measurement data including the first, second, and third pattern data;
measuring a pattern density of the pattern density measurement data;
adjusting shapes of patterns in the third pattern data based on a comparison of the measured density value and a reference density so as to form fourth pattern data; and
forming final pattern data including the first, second, and fourth pattern data.

2. The method as claimed in claim 1, wherein:
the first pattern data is active pattern data,
the second pattern data is gate pattern data, and
the third and fourth pattern data are dummy pattern data.

3. The method as claimed in claim 1, wherein the fourth pattern data has patterns that are obtained by adjusting at least one of a width, a length and an interval of patterns in the third pattern data.

4. The method as claimed in claim 3, wherein the fourth pattern data includes patterns that are obtained by adjusting at least one of the widths or lengths of the patterns in the third pattern data to be proportional to a pattern density of the pattern density measurement data or the intervals of the patterns in the third pattern data to be inversely proportional to the pattern density of the pattern density measurement data.

5. The method as claimed in claim 1, wherein the first pattern data and the third pattern data or fourth pattern data are incorporated into one pattern data.

6. A method of forming pattern data for a semiconductor device, the method comprising:
forming reference pattern data;
forming first pattern data having different pattern densities;
forming second pattern data;
measuring a pattern density by overlapping the reference pattern data and the second pattern data; and
selecting first pattern data corresponding to the measured pattern density among the first pattern data having different pattern densities.

7. The method as claimed in claim 6, wherein the first pattern data is active pattern data of the semiconductor device, and
the second pattern data is gate pattern data of the semiconductor device.

8. The method as claimed in claim 6, wherein the reference pattern data is active pattern data of the semiconductor device.

9. The method as claimed in claim 6, wherein the first pattern data having different pattern densities include main pattern data and dummy pattern data.

10. The method as claimed in claim 9, wherein the main pattern data has fixed shape and size, and the dummy pattern data has different shapes and sizes.

11. A method of forming a pattern for a semiconductor device, the method comprising:
forming a first pattern;
forming a second pattern;
measuring a total pattern density when the first pattern and the second pattern overlap each other;
comparing the measured density and a reference pattern density to form a third pattern; and
forming a final pattern in which the second pattern and the third pattern overlap each other.

12. The method as claimed in claim 11, wherein the first pattern and the third pattern are active patterns, and the second pattern is a gate pattern.

13. The method as claimed in claim 11, wherein the third pattern has patterns that are obtained by adjusting at least one of a width, a length, and an interval of a pattern in the first pattern.

14. The method as claimed in claim 13, wherein the widths and lengths of some patterns in the third pattern are adjusted to be in inverse proportion to the total pattern density, and the intervals of some patterns in the third pattern are adjusted to be in proportion to the total pattern density.

15. A semiconductor device comprising:
a first semiconductor element that has a first main pattern density and a first dummy pattern density; and
a second semiconductor element that has a second main pattern density and a second dummy pattern density,
wherein a ratio of the first main pattern density and the second main pattern density is inversely proportion to a ratio of the first dummy pattern density and the second dummy pattern density.

16. The semiconductor device as claimed in claim 15, wherein a difference between the first and second dummy pattern densities is a difference in width, length, or interval of dummy patterns.

17. The semiconductor device as claimed in claim 16, wherein the width and length of each of the dummy patterns is inversely proportion to a difference between the first and second main pattern densities, and the interval between the dummy patterns is proportional to the difference between the first and second main pattern densities.

18. The semiconductor device as claimed in claim 16, wherein the dummy patterns are a plurality of linear or segmental patterns that are formed parallel to each another.

19. The semiconductor device as claimed in claim 16, wherein the dummy patterns are a plurality of at least one of square patterns and polygonal patterns.

20. The semiconductor device as claimed in claim 15, wherein the dummy patterns are separated from the conductive patterns in the semiconductor device.
